(19) United States
(12) Patent Application Publication
(10) Pub. No.: US 2025/0301666 A1
(43) Pub. Date: Sep. 25, 2025

(54) 3D HETEROGENEOUSLY INTERCONNECTED MEMORY

(71) Applicant: MACRONIX INTERNATIONAL CO., LTD., HSINCHU (TW)

(72) Inventors: Han-Wen HU, Hsinchu (TW); Yung-Chun LI, New Taipei City (TW); Hang-Ting LUE, Hsinchu (TW); Chih-Chang HSIEH, Hsinchu (TW); Chung-Kuang CHEN, Hsinchu (TW); Yin-Jen CHEN, Hsinchu (TW)

(73) Assignee: MACRONIX INTERNATIONAL CO., LTD., HSINCHU (TW)

(21) Appl. No.: 18/612,605

(22) Filed: Mar. 21, 2024

(51) Int. Cl. H10B 80/00; H01L 25/00; H01L 25/18

(52) U.S. Cl. CPC H10B 80/00; H01L 25/18; H01L 25/50

(57) ABSTRACT

A 3D heterogeneously interconnected memory provides improved performance as well as reduced cost for non-volatile memory. A plurality of interconnection techniques is used to interconnect a plurality of dice using 3D stacking of the dice. One of the dice implements an array of memory strings to provide non-volatile storage. Another one of the dice implements logic circuits to improve performance and/or reduce cost associated with implementing a memory component using the array of memory strings. Example interconnection techniques use direct bonding, through-array vias, through-array contacts, and/or through-silicon vias.

### BACKGROUND

### Field

This disclosure relates to 3D memory implemented using stacked elements coupled by different types of interconnection technologies.

### Description of Related Art

Data produced by multimedia applications is exploding and thus demand for data storage is rapidly increasing. Reducing flash memory cost per bit, increasing bit density (Gb/mm²), and improving system level performance are therefore of paramount importance. In response, flash memory architecture (e.g., as implemented in NAND flash memory) is evolving from 2D structures to 3D structures. As a specific example, 3D NAND uses Circuit under Array (CuA) technology to reduce chip size by placing peripheral circuits under a 3D NAND array.

Further reducing the cost per bit and increasing bit density is provided by increasing stacked layers in a 3D NAND array. However, reduction of the area of the peripheral circuits is less than that of the 3D NAND array, thus limiting improvement provided by CuA technology.

Thus, what is needed are techniques that enable improving reduction of the area of peripheral circuitry, as well as improving overall cost per bit, bit density, and system level performance.

### SUMMARY

A system of one or more computers is configurable to perform particular operations or actions by virtue of having software, firmware, hardware, or a combination of them installed on the system that in operation causes or cause the system to perform the actions. One or more computer programs is configurable to perform particular operations or actions by virtue of including instructions that, when executed by data processing apparatus, cause the apparatus to perform the actions.

A first aspect includes a memory component that includes an array of memory strings coupled to a Bit Line (BL) and a Common Source Line (CSL), the BL and the CSL enabled to transmit a plurality of signals; feature logic circuitry; memory logic circuitry; a first one or more conductors formed through a corresponding one or more Through-Array Vias (TAVs) enabling communication between the feature logic circuitry and the memory logic circuitry; and a second one or more conductors formed to contact a corresponding one or more Through-Array Contacts (TACs), where at least one of the plurality of signals is transmitted to at least one of the second one or more conductors.

Aspects optionally include one or more of the following features. The memory component where the BL is coupled to the memory logic circuitry using one of the TACs. The BL is coupled to the memory logic circuitry using direct bonding. A feature logic integrated circuit die optionally includes the feature logic circuitry and a memory logic integrated circuit die optionally includes the memory logic circuitry. A memory array die optionally includes the array of memory strings. A first operating voltage of the feature logic integrated circuit die is less than a second operating voltage of the memory logic integrated circuit die. The feature logic circuitry optionally includes one or more of: page buffer circuitry, finite state machine circuitry, on-demand operation circuitry, Quality of Service (QOS) boosting circuitry, read/write performance improving circuitry, Input/Output (I/O) circuitry, Field Programmable Gate Array (FPGA) circuitry, one or more logic circuits enabled to operate at a lower voltage than the memory logic circuitry, and NAND interface circuitry. The feature logic circuitry optionally includes logic circuitry enabled to enhance performance of AI operations, that optionally includes any one or more of: an accumulator with shift-and-add and/or inversion operations, logic circuitry to quickly determine a count and compare the count to another value, first one or more registers enabled to retain intermediate data, and second one or more registers enabled to store input patterns. The feature logic circuitry optionally includes memory reliability circuitry, which is enabled to perform any one or more of: Cyclic Redundancy Check (CRC) operations, checksum operations, threshold voltage tracking operations, and error handling flow operations, one or more of the error handling flow operations enabling error correction according to one or more error correcting codes. The feature logic circuitry optionally includes asynchronous independent plane operation circuitry, which is enabled control the array of memory strings to perform at least one of (1) asynchronous independent plane program operations and (2) asynchronous independent plane erase operations. The memory logic circuitry optionally includes one or more of: charge pump circuitry, sense amplifier circuitry, programming circuitry, Word Line Driver (WLD) circuitry, String Select Line (SSL) driver circuitry, Ground Select Line (GSL) driver circuitry, one or more transistors coupled to a sense amplifier where the one or more transistors optionally include one or more BL clamping transistors and/or one or more BL precharge transistors, and CSL driver circuitry. The array of memory strings is implemented according to memory technology that optionally includes one or more of: Resistive Random Access read/write Memory (ReRAM) technology, phase change memory technology, Spin-Transfer Torque Resistive Random Access read/write Memory (STT-RAM) technology, NAND-based flash memory technology, and NOR-based flash memory technology. Variations of the described aspects optionally include hardware, a method or process, or computer software on a computer-accessible medium.

A second aspect includes a method that includes forming first interconnections between a memory logic die and a feature logic die using a first one or more conductors formed through a corresponding one or more Through-Array Vias (TAVs), and forming second interconnections between an array die and the memory logic die using a second one or more conductors formed to contact a corresponding one or more Through-Array Contacts (TACs); where the array die optionally includes an array of memory strings coupled to a Bit Line (BL) and a Common Source Line (CSL), the BL and the CSL transmitting a plurality of signals, the memory logic die optionally includes memory logic circuitry, the feature logic die optionally includes feature logic circuitry, the first interconnections enable communication between the feature logic circuitry and the memory logic circuitry using the first one or more conductors, and the second interconnections enable transmission of at least one of the plurality of signals to at least one of the second one or more conductors. Other variations of this aspect include corresponding computer systems, apparatus, and computer programs recorded on one or more computer storage devices, each configured to perform the actions of the methods.

Aspects optionally include one or more of the following features. The method where the memory logic die is one of a plurality of memory logic dice of a memory logic wafer, the feature logic die is one of a plurality of feature logic dice of a feature logic wafer, the forming of the first interconnections optionally includes forming interconnections between the memory logic wafer and the feature logic wafer. The array die is one of a plurality of array dice of an array wafer, the memory logic die is one of a plurality of memory logic dice of a memory logic wafer, the forming of the second interconnections optionally includes forming interconnections between the array wafer and the memory logic wafer. Variations of the described aspects optionally include hardware, a method or process, or computer software on a computer-accessible medium.

A third aspect includes the memory component that includes an array of memory strings coupled to a Bit Line (BL) and a Common Source Line (CSL), the BL and the CSL transmitting a plurality of signals; feature logic circuitry; memory logic circuitry; a first one or more conductors formed through a corresponding one or more through vias enabling communication between the feature logic circuitry and the memory logic circuitry; and a second one or more conductors formed to contact a corresponding one or more direct bonds, and where at least one of the plurality of signals is transmitted to at least one of the second one or more conductors. Variations of the described aspects optionally include hardware, a method or process, or computer software on a computer-accessible medium.

Aspects optionally include one or more of the following features. The memory component where the through vias optionally include Through-Array Vias (TAVs) that extend through the array, and the BL and the CSL are coupled to respective ones of the second one or more conductors. The through vias optionally include Through-Array Vias (TAVs) that extend through the array, and the BL is coupled to the memory logic circuitry by a direct bond. The through vias optionally include Through-Array Vias (TAVs) that extend through the array, and the BL is coupled to the feature logic circuitry by a direct bond. The through vias optionally include through silicon vias, and the BL and the CSL are coupled to respective ones of the second one or more conductors.

Variations of the described aspects optionally include hardware, a method or process, or computer software on a computer-accessible medium.

### BRIEF DESCRIPTION OF THE DRAWINGS

FIG. 1 illustrates an example of a 3D heterogeneously interconnected memory.

FIGS. 2A, 2B, 2C, 2D, 2E, and 2F illustrate respective examples of 3D heterogeneously interconnected memory.

FIG. 3 illustrates two example fabrication flows for a 3D heterogeneously interconnected memory.

FIGS. 4 and 5 respectively illustrate first and second example floor plans for an integrated circuit die of a 3D heterogeneously interconnected memory.

FIG. 6 illustrates area trends for array and non-array portions of memory components.

FIG. 7 illustrates an example 3D heterogeneously interconnected memory pin assignment.

### DETAILED DESCRIPTION

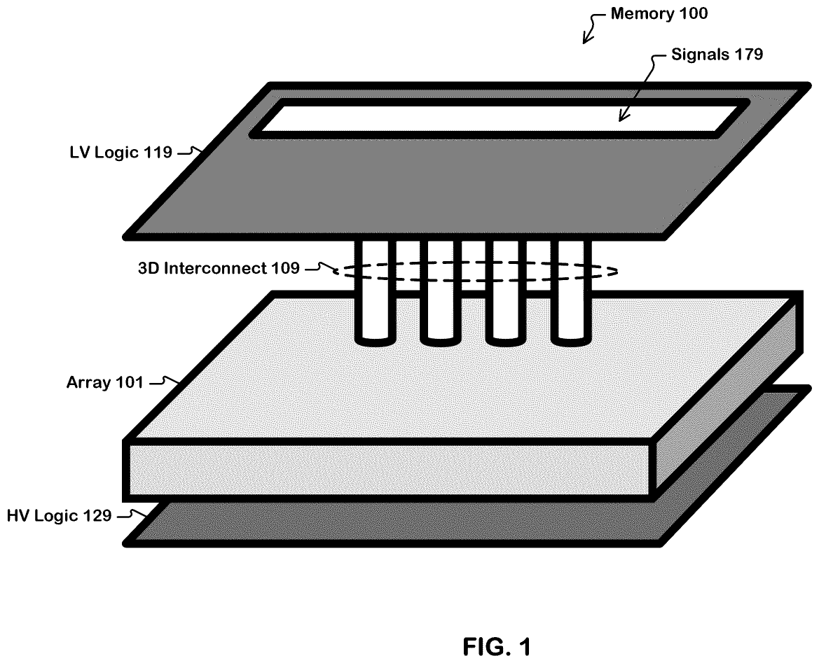

A detailed description of techniques relating to a 3D heterogeneously interconnected memory is provided with reference to FIGS. 1, 2A, 2B, 2C, 2D, 2E, 2F, 3, 4, 5, 6, and 7.

3D heterogeneously interconnected memory techniques enable reduction of the area of peripheral circuitry as well as improvement of overall cost per bit, bit density, and system level performance. For example, features are provided to improve QoS and read/write performance. An improved NAND interface enables PCIe Gen5 performance. An improvement to reduce cost per bit and/or increase bit density is provided by increasing voltage levels in one NAND cell, resulting in a small Vt window that increases raw bit error rate and program-verify complexity. To overcome the increases in raw bit error rate and program-verify complexity, logic circuitry is provided to improve error correction and to efficiently control program-verify operations, e.g., via one or more dedicated finite state machines. The features to improve QoS and read/write performance, the improved NAND interface, and the logic circuitry to improve error correction and to efficiently control program-verify operations, as well as other operations, such as on-demand operations are formed in one or more integrated circuit dice that are stacked in a 3D heterogeneously interconnect memory, as described herein. The stacking of the 3D heterogeneously interconnect memory enables these improvements without significant increases to overall memory component area.

A 3D heterogeneously interconnected memory provides improved performance as well as reduced cost for non-volatile memory. A plurality of interconnection techniques is used to interconnect a plurality of dice using 3D stacking of the dice. One of the dice implements an array of memory strings to provide non-volatile storage. Another one of the dice implements logic circuits to improve performance and/or reduce cost associated with implementing a memory component using the array of memory strings. Example interconnection techniques use direct bonding, through-array vias, through-array contacts, and/or through-silicon vias.

One or more flow diagrams are described herein. Processing described by the flow diagrams is implementable and/or directable using processors programmed using computer programs stored in memory accessible to computer systems and executable by the processors, using dedicated logic hardware (including field programmable integrated circuits), and using various combinations thereof. Various actions are combinable, performable in parallel, and/or performable in a different sequence without affecting processing achieved. In some cases, a rearrangement of actions achieves identical results only if certain other changes are made as well. In other cases, a rearrangement of actions achieves identical results only if certain conditions are satisfied. Furthermore, for clarity, some of the flow diagrams herein omit certain some actions not necessary for understanding the disclosed techniques. Various additional actions are performable before, after, and/or between the illustrated actions.

Examples of selected acronyms, mnemonics, and abbreviations used in the description are as follows.

(Acronym/Mnemonic/Abbreviation) Example

(2FeFET) Two Ferroelectric Field Effect Transistor
(2T0C (DRAM-like device)) Two-Transistor Zero-Capacitor
(2TR2R) Two Transistor Two Resistor
(AI) Artificial Intelligence
(BL) Bit Line
(CbA) Circuit-bonded-Array
(CRC) Cyclic Redundancy Check
(CSL) Common Source Line
(CuA) Circuit-under-Array
(DDR) Double Data Rate
(DRAM) Dynamic Random Access read/write Memory
(FeFET) Ferroelectric Field-Effect Transistor
(FPGA) Field Programmable Gate Array
(FSM) Finite State Machine
(GSL) Ground Select Line
(HV) High Voltage
(I/O) Input/Output
(LV) Low Voltage
(NAND) Not AND; e.g., series connection of devices forming a memory
string
(NOR) Not OR; e.g., parallel connection of devices forming a memory
string
(NVM) Non-Volatile Memory
(PB) Page Buffer
(QoS) Quality of Service
(RAM) Random Access read/write Memory
(ReRAM) Resistive Random Access read/write Memory
(SONOS (memory)) Silicon-Oxide-Nitride-Oxide-Silicon (memory)
(SSL) String Select Line
(STT-RAM) Spin-Transfer Torque Resistive Random Access read/
write Memory
(TA) Through-Array
(TAC) Through-Array Contact
(TACc) Through-Array Contact conductor, e.g., a conductor formed
coupled to a TAC
(TAV) Through-Array Via
(TAVc) Through-Array Via conductor, e.g., a conductor formed inside
a TAV
(TSV) Through-Silicon Via
(TSVc) Through-Silicon Via conductor, e.g., a conductor formed inside
a TSV
(WL) Word Line
(WLD) Word Line Driver

An example of a memory string is a plurality of series-connected memory devices. An example of a memory device is an element enabled to store information to indicate one of at least two mutually exclusive states of the memory device. The states are settable via programming the memory device and are readable via activating a control input of the memory device. In several types of memory devices (e.g., floating gate memory devices), the programming is via configuring a threshold voltage of the memory device and the control input is a control gate input. The configuring is also referred to as programming the memory device (e.g., to a one or a zero, or some other value), and is also referred to as storing the value (e.g., a one or a zero, or some other value).

An example of an array of memory strings is one or more memory strings arranged to store one or more words of information and accessible for reading and writing the information.

Examples of a through via include a TSV and a TAV.

An example of a TSV is a hole partially or entirely through a silicon-based material. Examples of the silicon-based material include a wafer, circuitry formed on a wafer, and/or insulating material. The hole has a major axis orthogonal to a major surface of the silicon-based material. The cross section of the hole parallel to the major surface is, e.g., circular, elliptical, or rectangular. The TSV is formed to accommodate a conductor (e.g., a TSVc), such as to couple a signal from one die to another. Using a TSV to couple signals from one die to another corresponds to a TSV interconnect technique.

An example of a TAV is a hole through an array die, such as an array die that includes an array of memory strings. The hole has a major axis orthogonal to a major surface of the array die. The cross section of the hole parallel to the major surface is, e.g., circular, elliptical, or rectangular. The TAV is formed to accommodate a conductor (e.g., a TAVc), such as to couple a signal from two dice mounted on opposing major surfaces of the array die. Using a TAV to interconnect dice corresponds to a TAV interconnect technique.

An example of TAC is a contact that is formed to enable a low-resistivity electrical connection between a conductor (e.g., a TACc) and a signal of an array die. Using a TAC to interconnect dice corresponds to a TAC interconnect technique.

An example of stacking circuitry on different die is direct bonding, e.g., using micro balls of solder to interconnect one die to another and corresponds to a direct bonding interconnect technique, such as used in CbA interconnect technology. An example of stacking circuitry within a die is forming, e.g., non-array circuitry on lower layers of the die followed by forming array circuitry on upper layers of the die (above the non-array circuitry), such as used in CuA interconnect technology.

Examples of interconnect techniques usable for a 3D heterogeneously interconnect memory include the TSV interconnect technique, the TAV interconnect technique, the TAC interconnect technique, and the direct bonding interconnect technique.

### 3D Heterogeneously Interconnected Memory Concepts

FIG. 1 illustrates an example of a 3D heterogeneously interconnected memory, as Memory 100. Memory 100 comprises Array 101 and LV Logic 119 optionally coupled by 3D Interconnect 109. Memory 100 further comprises HV Logic 129 optionally coupled by 3D Interconnect 109 to LV Logic 119. Array 101 comprises an array of memory strings and optionally comprises associated circuitry to implement non-volatile storage, such as in a vertical 3D NAND array. LV Logic 119 comprises (low-voltage) logic circuitry, such as to process information stored in Array 101. LV Logic 119 further comprises Signals 179, representative of communication between LV Logic 119 and either or both of Array 101 and HV Logic 129, e.g., using 3D Interconnect 109. HV Logic 129 comprises (high-voltage) logic circuitry, such as to sense BLs of Array 101 and/or to drive CSLs of Array 101.

3D Interconnect 109 enables communication between LV Logic 119 and either one or both of Array 101 and HV Logic 129. 3D Interconnect 109 comprises one or more TAVs, one or more TACs, and/or one or more TSVs. As a first example, 3D Interconnect 109 enables communication between page buffer logic circuitry of LV Logic 119 and outputs of sense amplifiers of HV Logic 129. As a second example, 3D Interconnect 109 enables communication between QoS logic circuitry of LV Logic 119 and the memory strings of Array 101. Array 101 and HV Logic 129 are optionally interconnected by direct bonding.

Each of Array 101, LV Logic 119, and HV Logic 129 is fabricated according to a respective integrated circuit fabrication process. As a first example, LV Logic 119 is fabricated according to an LV process and Array 101 and HV Logic 129 are fabricated according to an NVM-compatible HV process. As a second example, LV Logic 119 is fabricated according to an LV process, Array 101 is fabricated according to an NVM-compatible process, and HV Logic 129 is fabricated according to an HV process (that, e.g., is not specifically NVM-compatible). Each of the LV, NVM-compatible HV, and HV processes is according to respective operating voltages, minimum dimensions, oxide thicknesses, voltage thresholds, and so forth, according to efficient implementation of respective circuitry fabricated in the process.

Array 101, LV Logic 119, and HV Logic 129 are fabricated according to a plurality of integrated circuit dice. As a first example, each of LV Logic 119, Array 101, and HV Logic 129 is fabricated as a respective integrated circuit die. As a second example, Array 101 and HV Logic 129 are fabricated collectively as a first integrated circuit die, and LV Logic 119 is fabricated as a second integrated circuit die. As a third example, Array 101 and LV Logic 119 are fabricated collectively as a first integrated circuit die, and HV Logic 129 is fabricated as a second integrated circuit die.

Any one or more of Array 101, LV Logic 119, and/or HV Logic 129 are each individually fabricated as one or more integrated circuit dice. As a first example, Array 101 is fabricated as a pair of integrated circuit dice (e.g., each comprising respective pluralities of memory strings), and each of LV Logic 119 and HV Logic 129 is fabricated as a respective single integrated circuit dice. As a second example, LV Logic 119 is fabricated as a plurality of integrated circuit die, and each of Array 101 and HV Logic 129 is fabricated as a respective single integrated circuit die.

Communication between LV Logic 119, Array 101, and HV Logic 129 is enabled by a plurality of interconnection techniques. A TAV technique enables communication between LV Logic 119 and HV Logic 129 through Array 101 using a via between parallel surfaces of Array 101 (e.g., vertically). A TAC technique enables communication between Array 101 and either of LV Logic 119 and HV Logic 129 using a conductive element originating on one surface of Array 101 and terminating at a contact element of Array 101. A direct bonding technique enables communication between Array 101 and HV Logic 129. Thus, communication between LV Logic 119, Array 101, and HV Logic 129 collectively is enabled by heterogeneous techniques, and Memory 100 is an example of a 3D heterogeneously interconnected memory.

Various examples of LV Logic 119 are implemented in technology such as 180 nm, 130 nm, or 90 nm technologies. LV Logic 119 is an example of feature logic circuitry (e.g., as implemented in a feature logic integrated circuit) enabled to perform various operations such as to improve performance. Various examples of LV Logic 119 include page buffer circuitry, FSM circuitry, on-demand operation circuitry, Qos boosting circuitry, read/write performance improving circuitry, I/O circuitry, FPGA circuitry, logic circuitry enabled to enhance performance of AI operations, one or more logic circuits enabled to operate at a lower voltage than memory logic circuitry, memory string error circuitry that enables error-free and/or error-tolerant accessing of information stored in the array of memory strings, asynchronous independent plane operation circuitry, and NAND interface circuitry (e.g., such as enabled to interface to a PCIe Gen 5 compatible interface).

Examples of the logic circuitry enabled to enhance performance of AI operations include an accumulator with shift-and-add and/or inversion operations, logic circuitry to quickly determine a count and compare the count to another value, registers enabled to retain intermediate data, and registers enabled to store input patterns.

Examples of operations the memory string error circuitry is enabled to perform include CRC operations, checksum operations, threshold voltage tracking operations, and error handling flow operations. The error handling flow operations enable error correction such as by using one or more error-correcting decoding modules and/or one or more error-correcting encoding modules, that, e.g., the memory reliability circuitry includes. The error-correcting decoding modules are enabled to correct errors according to one or more error correcting codes. The error-correcting encoding modules are enabled to encode information according to the error correcting codes to enable subsequent error-correcting decoding by the error-correcting decoding modules. The error correcting codes include Bose-Chaudhuri-Hocquenghem (BCH) codes, Low-Density Parity-Check (LDPC) codes, and other codes, such as codes that enable improved memory reliability.

The asynchronous independent plane operation circuitry is enabled to control the array of memory strings to perform asynchronous independent plane program operations, asynchronous independent plane erase operations, or both.

Various examples of HV Logic 129 are implemented in technologies enabled to operate at higher supply voltages than LV Logic 119. HV Logic 129 is an example of memory logic circuitry (e.g., as implemented in a memory logic integrated circuit) enabled to interface all or any portions of an array of memory strings to other elements. Various examples of HV Logic 129 include charge pump circuitry, sense amplifier circuitry, transistors coupled to sense amplifier circuitry (e.g., BL clamping transistors and/or BL precharge transistors), programming circuitry, WLD circuitry, SSL driver, and CSL driver circuitry.

Examples of 3D Interconnect 109 are from copper material enabling high-bandwidth internal transfers between, e.g., Array 101, LV Logic 119, and/or HV Logic 129.

### 3D Heterogeneously Interconnected Memory Examples

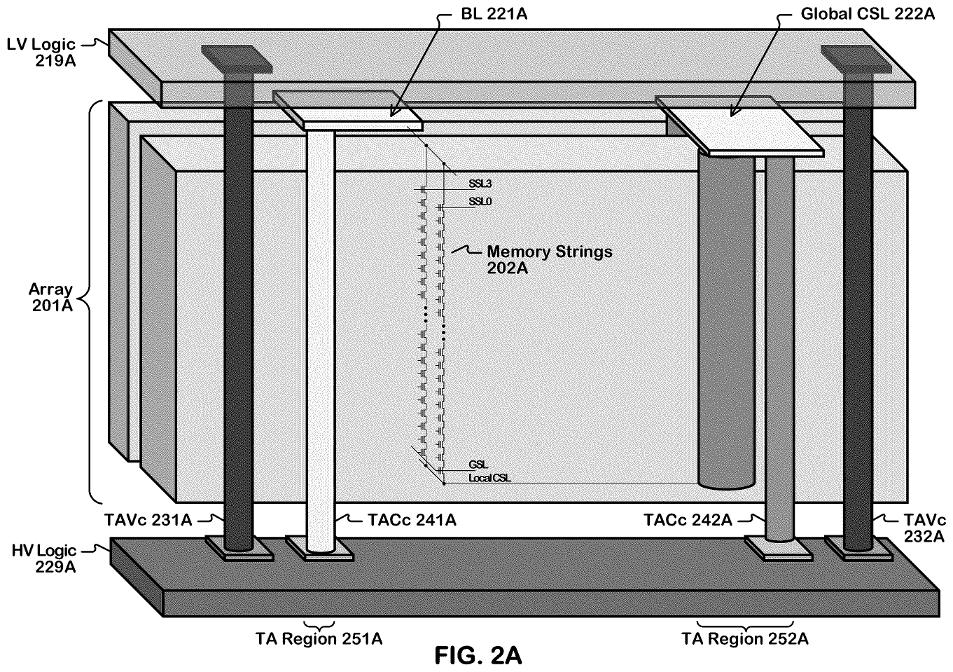

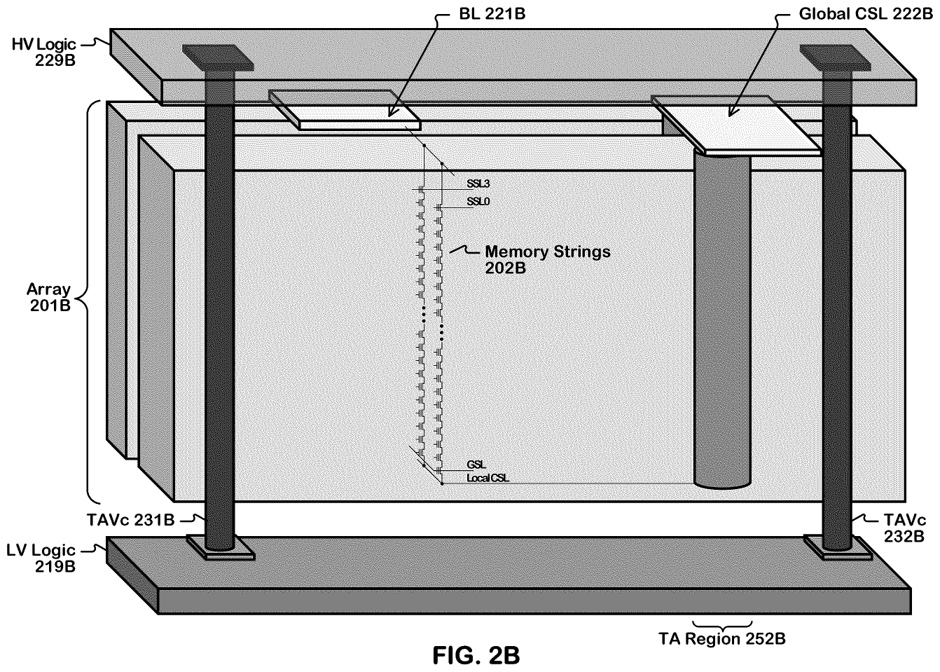

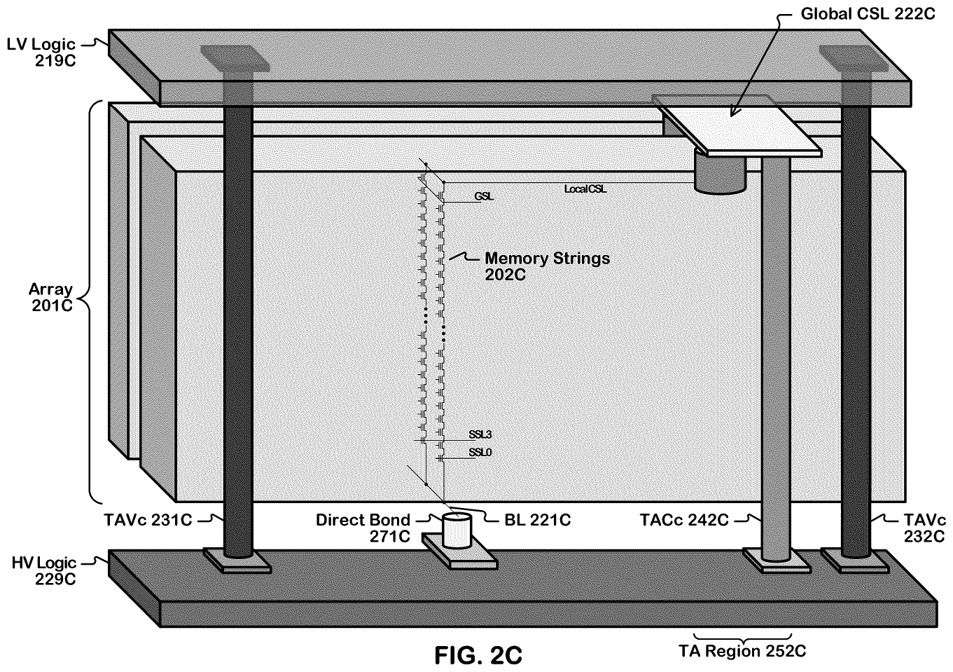

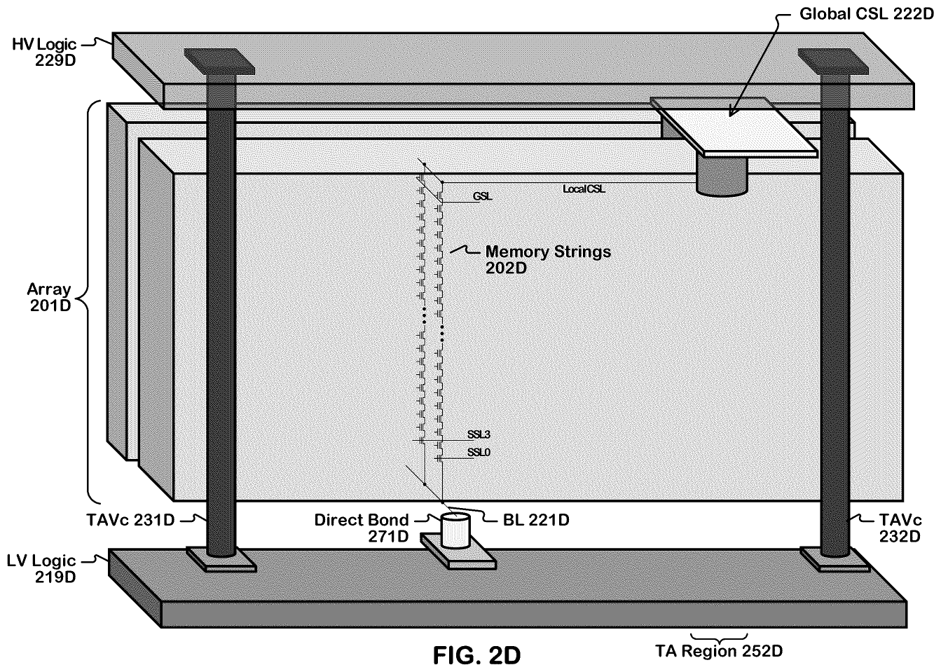

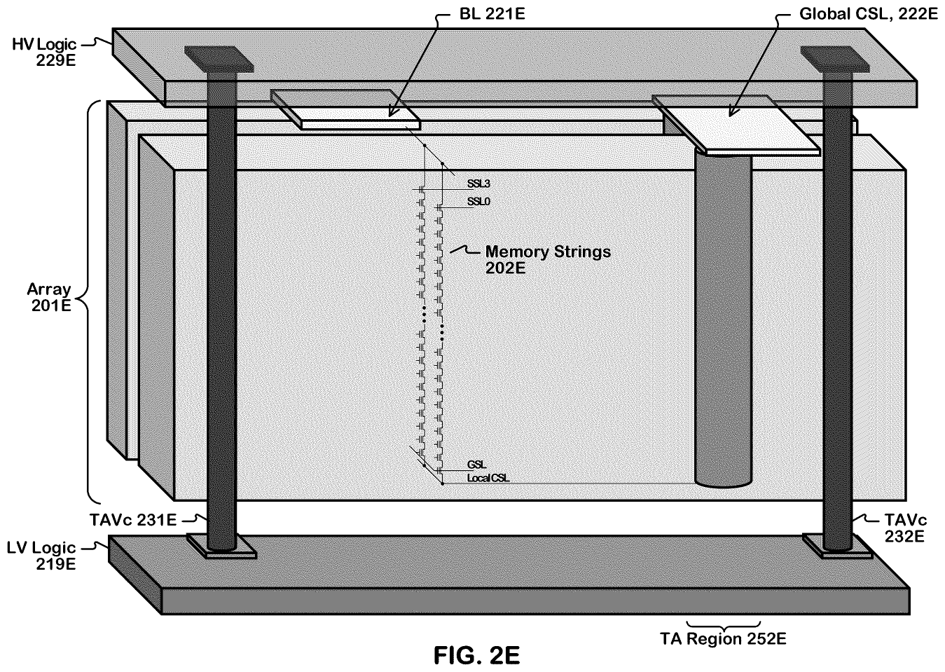

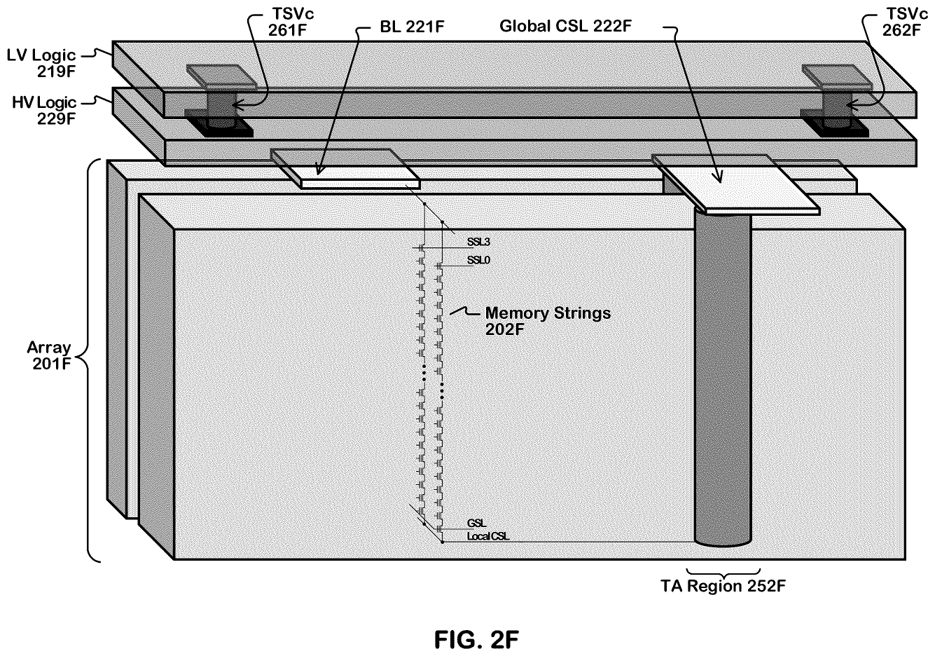

FIGS. 2A, 2B, 2C, 2D, 2E, and 2F illustrate respective examples of 3D heterogeneously interconnected memory and are referred to collectively as FIG. 2. The examples vary, e.g., according to stacking order of dice and interconnection techniques therebetween.

Throughout FIG. 2, element identifiers are suffixed to identify which of FIGS. 2A, 2B, 2C, 2D, 2E, and 2F an element is present in, enabling unambiguous identification of elements. For brevity, in some contexts elements present in each of FIGS. 2A, 2B, 2C, 2D, 2E, and 2F are referred to without the suffix. For example, Array 201A, Array 201B, Array 201C, Array 201D, Array 201E, and Array 201F are collectively referred to as Array 201.

Array 201 is a specific example of Array 101 (of FIG. 1), LV Logic 219 is a specific example of LV Logic 119 (of FIG. 1), and HV Logic 229 is a specific example of HV Logic 129 (of FIG. 1). The direct bonding, TAV, TAC, and TSV interconnect techniques described with respect to FIG. 2 are specific examples of 3D Interconnect 109 of FIG. 1.

FIG. 2A illustrates an example of 3D heterogeneously interconnected memory formed so that Array 201A is between LV Logic 219A and HV Logic 229A. The Array 201A includes Memory Strings 202A. LV Logic 219A is stacked “above” the surface of Array 201A that is nearest to the SSLs of Array 201A (illustrated as SSL3 and SSL0). HV Logic 229A is stacked “below” the surface of Array 201A that is nearest to the LocalCSL of Array 201A. Communication between BL 221A and HV Logic 229A (such as to a sense amplifier of HV Logic 229A) is enabled by the TAC technique using TACc 241A. Communication between HV Logic 229A and Global CSL 222A (such as from a CSL driver of HV Logic 229A) is enabled by the TAC technique using TACc 242A. Communication between LV Logic 219A and HV Logic 229A is enabled by the TAV technique using TAVc 231A and TAVc 232A. Thus, communication between LV Logic 219A, Array 201A, and HV Logic 229A is enabled by heterogeneous techniques, including the TAC and the TAV techniques.

TA Region 251A and TA Region 252A respectively indicate portions of Array 201A used for through-array capability associated respectively with TACc 241A and TACc 242A. TA Region 252A also indicates a portion of Array 201A used for through-array capability associated with the vertical portion of the LocalCSL connection to Global CSL 222A.

In some examples of 3D heterogeneously interconnected memory formed as illustrated in FIG. 2A, LV Logic 219A is comprised in a first die and a combination of Array 201A and HV Logic 229A is comprised in a second die. In some examples of 3D heterogeneously interconnected memory formed as illustrated in FIG. 2A, electrical, thermal, and/or mechanical interconnection between LV Logic 219A and a combination of Array 201A and HV Logic 229A uses a CbA technique. In some examples of 3D heterogeneously interconnected memory formed as illustrated in FIG. 2A, electrical, thermal, and/or mechanical interconnection between Array 201A and HV Logic 229A uses a CuA technique, e.g., HV Logic 229A is formed on lower layers of a die and Array 201A is then formed on upper layers of the die.

All or any portions of BL 221A and/or Global CSL 222A are fabricated variously as part of Array 201A, separately from Array 201A, or as part of forming the stack of LV Logic 219A, Array 201A, and HV Logic 229A illustrated in FIG. 2A.

FIG. 2B illustrates an example of 3D heterogeneously interconnected memory formed so that Array 201B is between HV Logic 229B and LV Logic 219B. The Array 201B includes Memory Strings 202B. HV Logic 229B is stacked “above” the surface of Array 201B that is nearest to the SSLs of Array 201B (illustrated as SSL3 and SSL0). LV Logic 219B is stacked “below” the surface of Array 201B that is nearest to the LocalCSL of Array 201B.

Communication between BL 221B and HV Logic 229B (such as to a sense amplifier of HV Logic 229B) is enabled by the direct bonding technique (omitted from FIG. 2B for clarity; a similar type of direct bonding is illustrated in FIG. 2C as Direct Bond 271C). Communication between Global CSL 222B and HV Logic 229B (such as from a CSL driver of HV Logic 229B) is enabled by the direct bonding technique (omitted from FIG. 2B for clarity; a similar type of direct bonding is illustrated in FIG. 2C as Direct Bond 271C). Communication between LV Logic 219B and HV Logic 229B is enabled by the TAV technique using TAVc 231B and TAVc 232B. Thus, communication between LV Logic 219B, Array 201B, and HV Logic 229B is enabled by heterogeneous techniques, including the direct bonding and the TAV techniques.

TA Region 252B indicates a portion of Array 201B used for through-array capability associated with the vertical portion of the LocalCSL connection to Global CSL 222B.

In some examples of 3D heterogeneously interconnected memory formed as illustrated in FIG. 2B, HV Logic 229B is comprised in a first die and a combination of Array 201B and LV Logic 219B is comprised in a second die. In some examples of 3D heterogeneously interconnected memory formed as illustrated in FIG. 2B, electrical, thermal, and/or mechanical interconnection between HV Logic 229B and a combination of Array 201B and LV Logic 219B uses a CbA technique. In some examples of 3D heterogeneously interconnected memory formed as illustrated in FIG. 2B, electrical, thermal, and/or mechanical interconnection between Array 201B and LV Logic 219B uses a CuA technique, e.g., LV Logic 219B is formed on lower layers of a die and Array 201B is then formed on upper layers of the die.

All or any portions of BL 221B and/or Global CSL 222B are fabricated variously as part of Array 201B, separately from Array 201B, or as part of forming the stack of LV Logic 219B, Array 201B, and HV Logic 229B illustrated in FIG. 2B.

FIG. 2C illustrates an example of 3D heterogeneously interconnected memory formed so that Array 201C is between LV Logic 219C and HV Logic 229C. The Array 201C includes Memory Strings 202C. LV Logic 219C is stacked “above” the surface of Array 201C that is nearest to the LocalCSL of Array 201C. HV Logic 229C is stacked “below” the surface of Array 201C that is nearest to the SSLs of Array 201C (illustrated as SSL3 and SSL0). Communication between BL 221C and HV Logic 229C (such as to a sense amplifier of HV Logic 229C) is enabled by the direct bonding technique using Direct Bond 271C. Communication between Global CSL 222C and Array 201C (such as from a CSL driver of HV Logic 229C) is enabled by the TAC technique using TACc 242C. Communication between LV Logic 219C and HV Logic 229C is enabled by the TAV technique using TAVc 231C and TAVc 232C. Thus, communication between LV Logic 219C, Array 201C, and HV Logic 229C is enabled by heterogeneous techniques, including the direct bonding, the TAC, and the TAV techniques.

TA Region 252C indicates portions of Array 201C used for through-array capability associated with TACc 242C and the vertical portion of the LocalCSL connection to Global CSL 222C.

In some examples of 3D heterogeneously interconnected memory formed as illustrated in FIG. 2C, LV Logic 219C is comprised in a first die and a combination of Array 201C and HV Logic 229C is comprised in a second die. In some examples of 3D heterogeneously interconnected memory formed as illustrated in FIG. 2C, electrical, thermal, and/or mechanical interconnection between LV Logic 219C and a combination of Array 201C and HV Logic 229C uses a CbA technique. In some examples of 3D heterogeneously interconnected memory formed as illustrated in FIG. 2C, electrical, thermal, and/or mechanical interconnection between Array 201C and HV Logic 229C uses a CuA technique, e.g., HV Logic 229C is formed on lower layers of a die and Array 201C is then formed on upper layers of the die.

All or any portions of BL 221C and/or Global CSL 222C are fabricated variously as part of Array 201C, separately from Array 201C, or as part of forming the stack of LV Logic 219C, Array 201C, and HV Logic 229C illustrated in FIG. 2C.

FIG. 2D illustrates an example of 3D heterogeneously interconnected memory formed so that Array 201D is between LV Logic 219D and HV Logic 229D. The Array 201D includes Memory Strings 202D. HV Logic 229D is stacked “above” the surface of Array 201D that is nearest to the LocalCSL of Array 201D. LV Logic 219D is stacked “below” the surface of Array 201D that is nearest to the SSLs of Array 201D (illustrated as SSL3 and SSL0). Communication between BL 221D and LV Logic 219D (such as to QoS logic circuitry of LV Logic 219D) is enabled by the direct bonding technique using Direct Bond 271D. Communication between Global CSL 222D and HV Logic 229D (such as from a CSL driver of HV Logic 229D) is enabled by the direct bonding technique (omitted from FIG. 2D for clarity; a similar type of direct bonding is illustrated as Direct Bond 271D). Communication between LV Logic 219D and HV Logic 229D is enabled by the TAV technique using TAVc 231D and TAVc 232D. Thus, communication between LV Logic 219D, Array 201D, and HV Logic 229D is enabled by heterogeneous techniques, including the direct bonding and the TAV techniques.

TA Region 252D indicates portions of Array 201D used for through-array capability associated with the vertical portion of the LocalCSL connection to Global CSL 222D.

In some examples of 3D heterogeneously interconnected memory formed as illustrated in FIG. 2D, HV Logic 229D is comprised in a first die and a combination of Array 201D and LV Logic 219D is comprised in a second die. In some examples of 3D heterogeneously interconnected memory formed as illustrated in FIG. 2D, electrical, thermal, and/or mechanical interconnection between HV Logic 229D and a combination of Array 201D and LV Logic 219D uses a ChA technique. In some examples of 3D heterogeneously interconnected memory formed as illustrated in FIG. 2D, electrical, thermal, and/or mechanical interconnection between Array 201D and LV Logic 219D uses a CuA technique, e.g., LV Logic 219D is formed on lower layers of a die and Array 201D is then formed on upper layers of the die.

All or any portions of BL 221D and/or Global CSL 222D are fabricated variously as part of Array 201D, separately from Array 201D, or as part of forming the stack of LV Logic 219D, Array 201D, and HV Logic 229D illustrated in FIG. 2D.

FIG. 2E illustrates an example of 3D heterogeneously interconnected memory formed so that Array 201E is between LV Logic 219E and HV Logic 229E. The Array 201E includes Memory Strings 202E. HV Logic 229E is stacked “above” the surface of Array 201E that is nearest to the SSLs of Array 201E (illustrated as SSL3 and SSL0). LV Logic 219 is stacked “below” the surface of Array 201E that is nearest to the LocalCSL of Array 201E. Communication between BL 221E and HV Logic 229E (such as to a sense amplifier of HV Logic 229E) is enabled by the direct bonding technique (omitted from FIG. 2E for clarity; a similar type of direct bonding is illustrated in FIG. 2D as Direct Bond 271D). Communication between Global CSL 222E and HV Logic 229E (such as from a CSL driver of HV Logic 229E) is enabled by the direct bonding technique (omitted from FIG. 2E for clarity; a similar type of direct bonding is illustrated in FIG. 2D as Direct Bond 271D). Communication between LV Logic 219E and HV Logic 229E is enabled by the TAV technique using TAVc 231E and TAVc 232E. Thus, communication between LV Logic 219E, Array 201E, and HV Logic 229E is enabled by heterogeneous techniques, including the direct bonding and the TAV techniques.

TA Region 252E indicates portions of Array 201E used for through-array capability associated with the vertical portion of the LocalCSL connection to Global CSL 222E.

In some examples of 3D heterogeneously interconnected memory formed as illustrated in FIG. 2E, HV Logic 229E is comprised in a first die and at least one of Array 201E and LV Logic 219E is comprised in a second die. In some examples of 3D heterogeneously interconnected memory formed as illustrated in FIG. 2E, electrical, thermal, and/or mechanical interconnection between HV Logic 229E and Array 201E uses a CbA technique. In some examples of 3D heterogeneously interconnected memory formed as illustrated in FIG. 2E, electrical, thermal, and/or mechanical interconnection between Array 201E and LV Logic 219E uses a CbA technique.

All or any portions of BL 221E and/or Global CSL 222E are fabricated variously as part of Array 201E, separately from Array 201E, or as part of forming the stack of LV Logic 219E, Array 201E, and HV Logic 229E illustrated in FIG. 2E.

FIG. 2F illustrates an example of 3D heterogeneously interconnected memory formed so that Array 201F is “below” both LV Logic 219F and HV Logic 229F. The Array 201F includes Memory Strings 202F. HV Logic 229F is stacked “above” the surface of Array 201F that is nearest to the SSLs of Array 201F (illustrated as SSL3 and SSL0) of Array 201F. LV Logic 219F is stacked “above” the surface of HV Logic 229F that is opposite Array 201F. Communication between BL 221F and HV Logic 229F (such as to a sense amplifier of HV Logic 229F) is enabled by the direct bonding technique (omitted from FIG. 2F for clarity; a similar type of direct bonding is illustrated in FIG. 2D as Direct Bond 271D). Communication between Global CSL 222F and Array 201F (such as from a CSL driver of HV Logic 229F) is enabled by the direct bonding technique (omitted from FIG. 2F for clarity; a similar type of direct bonding is illustrated in FIG. 2D as Direct Bond 271D). Communication between LV Logic 219F and HV Logic 229F is enabled by the TSV technique using TSVc 261F and TSVc 262F. Thus, communication between LV Logic 219F, Array 201F, and HV Logic 229F is enabled by heterogeneous techniques, including the direct bonding and the TSV techniques.

TA Region 252F indicates portions of Array 201F used for through-array capability associated with the vertical portion of the LocalCSL connection to Global CSL 222F.

In some examples of 3D heterogeneously interconnected memory formed as illustrated in FIG. 2F, HV Logic 229F is comprised in a first die and at least one of Array 201F and LV Logic 219F is comprised in a second die. In some examples of 3D heterogeneously interconnected memory formed as illustrated in FIG. 2F, electrical, thermal, and/or mechanical interconnection between HV Logic 229F and Array 201F uses a CbA technique. In some examples of 3D heterogeneously interconnected memory formed as illustrated in FIG. 2E, electrical, thermal, and/or mechanical interconnection between HV Logic 229F and LV Logic 219F uses a CbA technique.

All or any portions of BL 221F and/or Global CSL 222F are fabricated variously as part of Array 201F, separately from Array 201F, or as part of forming the stack of LV Logic 219F, Array 201F, and HV Logic 229F illustrated in FIG. 2F.

### 3D Heterogeneously Interconnected Memory Fabrication Example

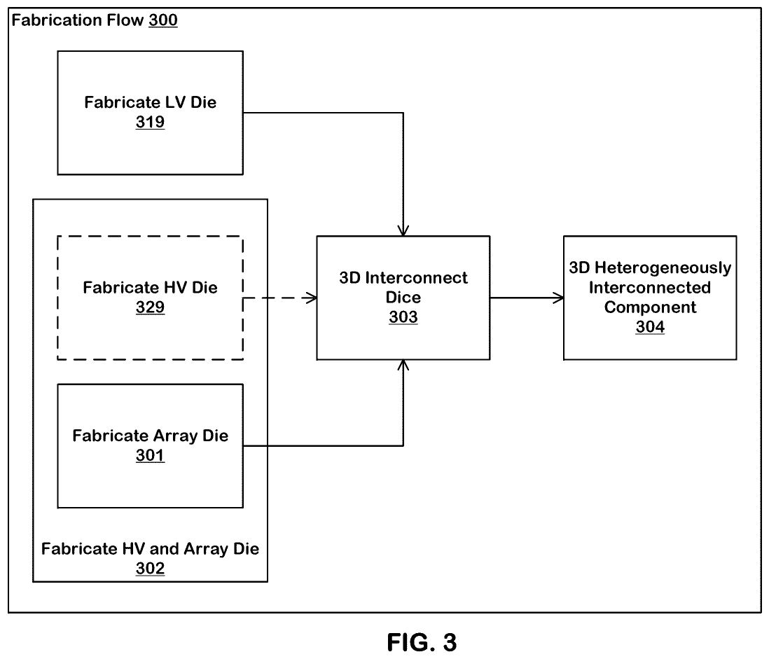

FIG. 3 illustrates two example fabrication flows for a 3D heterogeneously interconnected memory, as Fabrication Flow 300. Flow for a two-die fabrication flow begins with fabricating each of the two die respectively in Fabricate LV Die 319 and Fabricate HV and Array Die 302. Then the two dice fabricated are interconnected electrically, thermally, and/or mechanically to each other in 3D Interconnect Dice 303, enabling, e.g., communicating between the two dice. The result of the interconnecting is then provided in 3D Heterogeneously Interconnected Component 304. Flow for a three-die fabrication flow begins with fabricating each of the three die respectively in Fabricate LV Die 319, Fabricate HV Die 329, and Fabricate Array Die 301. Then the three dice fabricated are interconnected electrically, thermally, and/or mechanically to each other in 3D Interconnect Dice 303. As in the two-die fabrication flow, the result is then provided in 3D Heterogeneously Interconnected Component 304.

Fabricate LV Die 319 is a specific example of fabrication of LV Logic 119 of (FIG. 1) and/or LV Logic 219 (of FIG. 2), Fabricate HV Die 329 is a specific example of fabrication of HV Logic 129 (of FIG. 1) and/or HV Logic 229 (of FIG. 2), and Fabricate Array Die 301 is a specific example of fabrication of Array 101 (of FIG. 1) and/or Array 201 (of FIG. 2).

For example, an instance of LV Logic 219 (of FIG. 2) is fabricated in accordance with Fabricate LV Die 319. For another example, an instance of HV Logic 229 (of FIG. 2) is fabricated in accordance with Fabricate HV Die 329. For another example, an instance of Array 201 (of FIG. 2) is fabricated in accordance with Fabricate Array Die 301. For another example, an instance of HV Logic 229 and an instance of Array 201 are collectively fabricated in accordance with Fabricate HV and Array Die 302.

The interconnecting performed in 3D Interconnect Dice 303 is exemplified by the heterogeneous techniques as described with respect to FIG. 1 and/or FIG. 2, such as direct bonding, TAV, TAC, and TSV techniques.

Each of Fabricate LV Die 319, Fabricate HV Die 329, Fabricate Array Die 301, and Fabricate HV and Array Die 302 is according to a respective integrated circuit fabrication process. E.g., Fabricate LV Die 319 is according to the LV process (e.g., as described with respect to FIG. 1). E.g., Fabricate HV Die 329 is according to the HV process or the NVM-compatible HV process (e.g., as described with respect to FIG. 1). E.g., Fabricate Array Die 301 is according to the NVM-compatible process or the NVM-compatible HV process (e.g., as described with respect to FIG. 1). E.g., Fabricate HV and Array Die 302 is according to the NVM-compatible HV process (e.g., as described with respect to FIG. 1).

In a first aspect of FIG. 3, fabrication of dice (e.g., as in Fabricate LV Die 319, Fabricate HV Die 329, Fabricate Array Die 301, and/or Fabricate HV and Array Die 302) is representative of fabrication of a single die at a time, such as individual integrated circuit die produced from dicing a wafer, e.g., as produced by planar silicon fabrication techniques. In a second aspect of FIG. 3, fabrication of dice (e.g., as in Fabricate LV Die 319, Fabricate HV Die 329, Fabricate Array Die 301, and/or Fabricate HV and Array Die 302) is representative of fabrication of all or a portion of a wafer of a plurality of dice at a time, e.g., as produced by planar silicon fabrication techniques.

Regarding the first and second aspects of FIG. 3, the interconnecting performed in 3D Interconnect Dice 303 is respectively representative of fabricating a single component at a time (from individual die) or fabricating a plurality of components by interconnecting a plurality of wafers (each of respective pluralities of dice) at a time.

For example, a first wafer comprising a plurality of dice in accordance with LV Logic 219 (of FIG. 2) is interconnected to a second wafer comprising a plurality of dice in accordance with Array 201 (of FIG. 2), so that each individual die of the first wafer is interconnected to a respective individual die of the second wafer. Continuing with the example, the interconnected first and second wafers are then interconnected to a third wafer comprising a plurality of dice in accordance with HV Logic 229 (of FIG. 2), so that each individual die of the second wafer is interconnected to a respective individual die of the third wafer. Then the three interconnected wafers are diced into individual components, each including a single instance of a die in accordance with LV Logic 219, a single instance of a die in accordance with Array 201, and a single instance of a die in accordance with HV Logic 229.

In a first context, Fabricate LV Die 319, Fabricate HV Die 329, Fabricate Array Die 301, and Fabricate HV and Array Die 302 each correspond to fabrication of a single die. In a second context, any one or more of Fabricate LV Die 319, Fabricate HV Die 329, Fabricate Array Die 301, and/or Fabricate HV and Array Die 302 correspond to fabrication of a respective plurality of dice, variously identical to each other and/or different from each other.

As a first example, Fabricate Array Die 301 corresponds to fabricating two identical array dice, e.g., each comprising respective pluralities of memory strings. Continuing with the example, each of Fabricate LV Die 319 and Fabricate HV Die 329 corresponds to fabricating a respective single die. 3D Interconnect Dice 303 is then representative of interconnecting the four resultant dice. As a second example, Fabricate LV Die 319 corresponds to fabricating two LV dice, a first LV die enabled to perform a first set of operations and a second LV die enabled to perform a second set of operations, at least some of which are distinct from those of the first set of operations. Continuing with the example, each of Fabricate HV Die 329 and Fabricate Array Die 301 corresponds to fabricating a respective single die. 3D Interconnect Dice 303 is then representative of interconnecting the four resultant dice.

In one variation, 3D Interconnect Dice 303 corresponds forming a stack of two or three dice. In other variations, any one or more of Fabricate LV Die 319, Fabricate HV Die 329, Fabricate Array Die 301, and Fabricate HV and Array Die 302, correspond to fabricating a respective stack of dice. For example, Fabricate Array Die 301 corresponds to fabricating two identical array dice, e.g., each comprising respective pluralities of memory strings. Continuing with the example, each of Fabricate LV Die 319 and Fabricate HV Die 329 corresponds to fabricating a respective single die. 3D Interconnect Dice 303 is then representative of interconnecting the stack of two array dice and the other two dice into a four-dice stack.

### 3D Heterogeneously Interconnected Memory Example Floor Plans

Conceptually, enabling stacking of array and non-array portions of memory components by overlapping of an array die with a same-sized HV logic die and/or a same-sized LV logic die enables reducing area of the memory component, as illustrated by the following example floor plans.

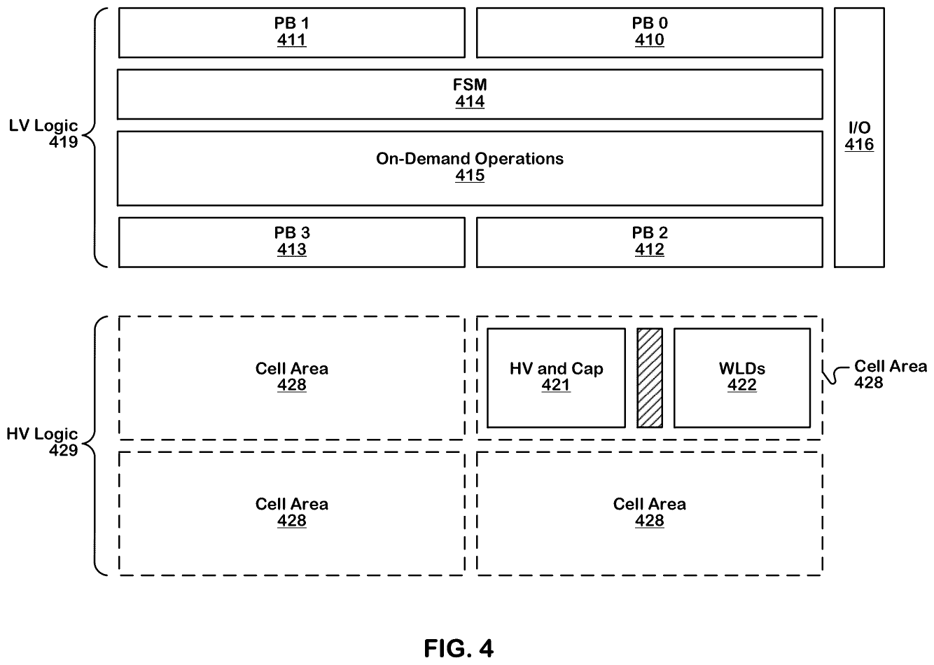

FIG. 4 illustrates first example floor plans for integrated circuit dice of a 3D heterogeneously interconnected memory. LV Logic 419 is an example floor plan for, e.g., an implementation of LV Logic 119 (of FIG. 1). HV Logic 429 is an example floor plan for, e.g., an implementation of HV Logic 129 (of FIG. 1).

LV Logic 419 comprises four instances of PB logic as PB 0 410, PB 1 411, PB 2 412, and PB 3 413. Each of the instances comprises one or more buffers that collectively operate to buffer pages of information of memory strings of an array die that is accessible to one or more elements of LV Logic 419. LV Logic 419 further comprises FSM 414, On-Demand Operations 415, and I/O 416. FSM 414 is enabled to perform sequencing, e.g., as relating to error management and/or correction, or as relating to program/verify operations. On-Demand Operations 415 is enabled to provide operations dynamically as-needed, such as to boost QoS, improve read/write performance of the array die, and/or to provide a high-speed interface for the array die. I/O 416 is enabled to communicate information between LV Logic 419 and other components.

HV Logic 429 comprises four instances of Cell Area 428. For clarity, only a single of the illustrated instances of Cell Area 428 is depicted in detail as comprising HV and Cap 421 and WLDs 422. HV and Cap 421 is enabled to generate high voltage (e.g., such as via a charge pump to enable programming the memory strings). WLDs 422 comprises a plurality of circuits each enabled to drive a respective WL of the memory strings. Optionally, a plurality of sense amplifiers to access information stored in the memory strings is comprised in HV and Cap 421 and/or WLDs 422.

Thus, overlapping a corresponding array die with LV Logic 419 and/or HV Logic 429 to form a 3D heterogeneously interconnected memory enables area reduction of a memory component.

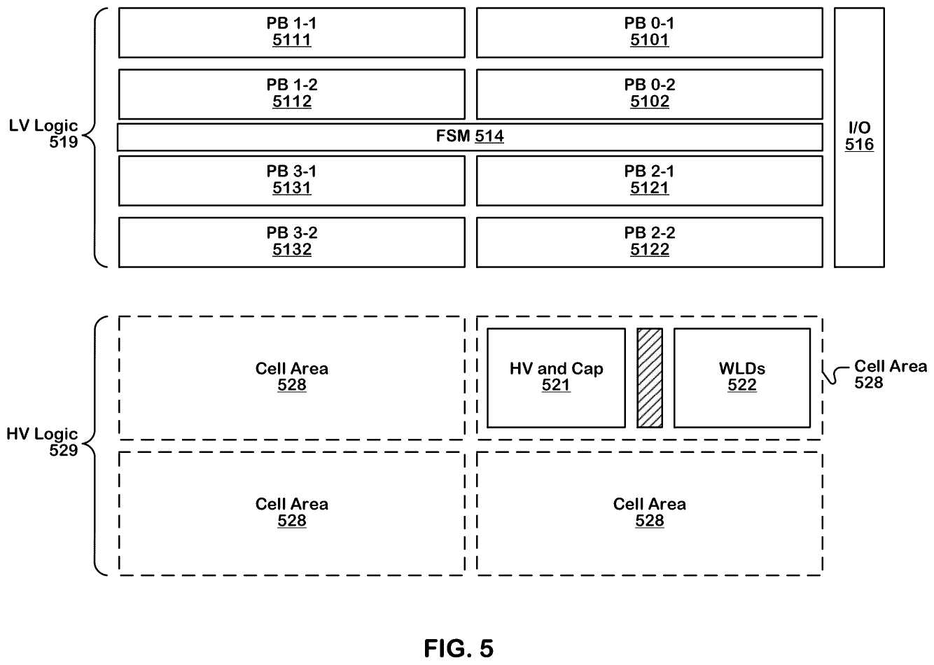

FIG. 5 illustrates second example floor plans for integrated circuit dice of a 3D heterogeneously interconnected memory. LV Logic 519 is an example floor plan for, e.g., an implementation of LV Logic 119 (of FIG. 1). HV Logic 529 is an example floor plan for, e.g., an implementation of HV Logic 129 (of FIG. 1).

LV Logic 519 comprises eight instances of PB logic as PB 0-1 5101 and PB 0-2 5102, PB 1-1 5111 and PB 1-2 5112, PB 2-1 5121 and PB 2-2 5122, as well as PB 3-1 5131 and PB 3-2 5132. Each of the instances comprises one or more buffers that collectively operate to buffer pages of information of memory strings of an array die that is accessible to one or more elements of LV Logic 519. The buffers comprise on-demand functions to provide operations dynamically as-needed, such as to double QoS and/or read/write performance of the array die, and/or to provide a high-speed interface for the array die. LV Logic 519 further comprises FSM 514 and I/O 516. FSM 514 is enabled to perform sequencing, e.g., as relating to error management and/or correction, or as relating to program/verify operations. I/O 516 is enabled to communicate information between LV Logic 519 and other components, such as the array die and/or HV Logic 529.

HV Logic 529 is, e.g., identical to HV Logic 429 (of FIG. 4), with elements Cell Area 528, HV and Cap 521, and WLDs 522 corresponding respectively to elements of Cell Area 428, HV and Cap 421, and WLDs 422 (of FIG. 4).

Thus, overlapping a corresponding array die with LV Logic 519 and/or HV Logic 529 to form a 3D heterogeneously interconnected memory enables area reduction of a memory component.

### 3D Heterogeneously Interconnected Memory Additional Information

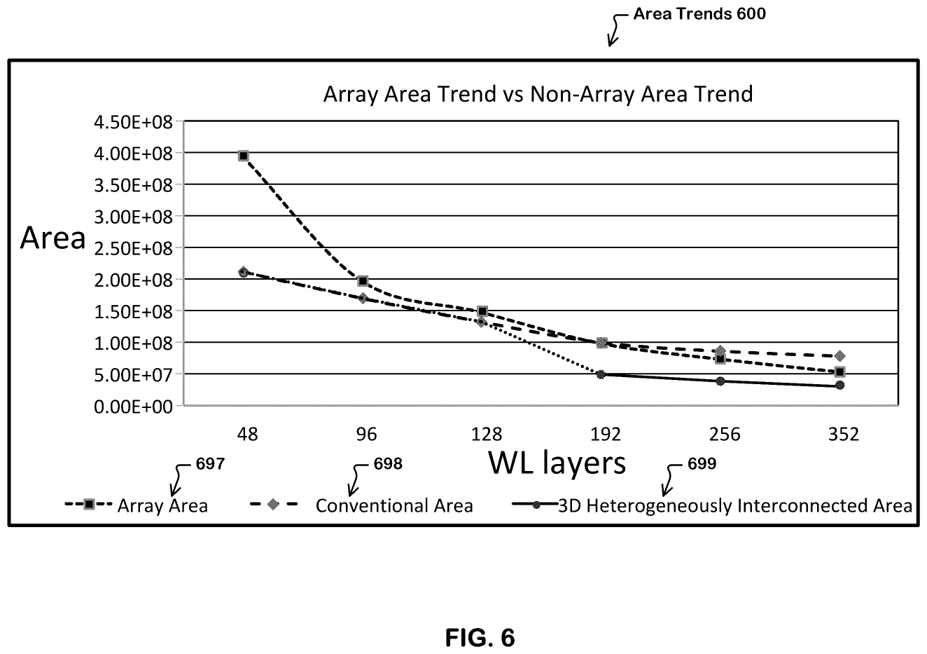

FIG. 6 illustrates area trends for array and non-array portions of memory components as Area Trends 600. The vertical axis corresponds to area and the horizontal axis corresponds to a number of WL layers. Array Area 697 represents area of memory strings of an array die. Conventional Area 698 represents area of a conventional implementation of non-array functionality (e.g., charge-pumps, sense amplifiers, and WLDs). 3D Heterogeneously Interconnected Area 699 represents area of a 3D heterogeneously interconnected memory implementation of the non-array functionality. As illustrated, 3D Heterogeneously Interconnected Area 699 enables implementations of memory components that are characterized by area used by the array, rather than by the area used by non-array functionality, as in conventional implementations, thus enabling reduced area.

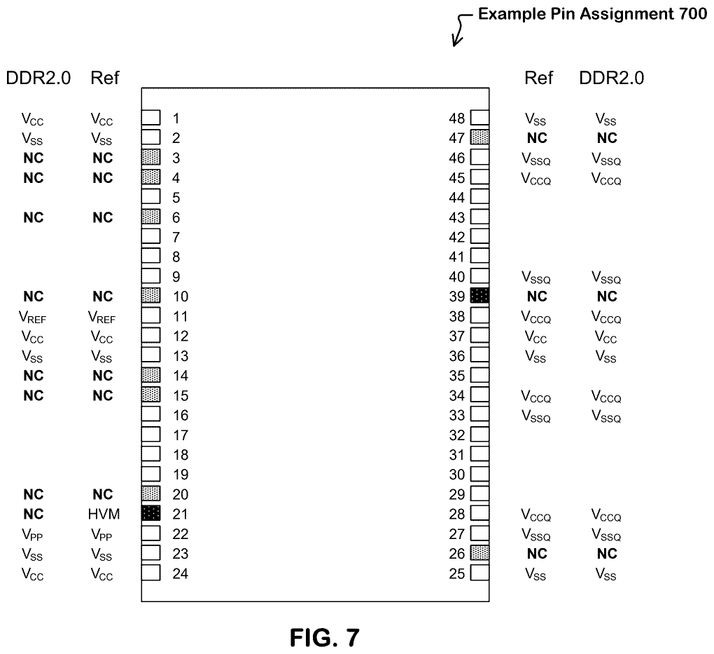

FIG. 7 illustrates an example 3D heterogeneously interconnected memory pin assignment, as Example Pin Assignment 700. Compared to a DDR2.0 implementation, Example Pin Assignment 700 provides for a plurality of voltage domains, e.g., any one or more of the NC pins in the Ref columns (e.g., any one or more of pins 3, 4, 6, 10, 14, 15, 20, 26, 39, and 47) are usable for a second voltage domain distinct from the voltage domain of the DDR2.0 implementation. The second voltage domain is usable, e.g., by LV Logic. Optionally, the second voltage domain is operated at a lower voltage than the DDR2.0 voltage domain, enabling power reduction (e.g., as switch/capacitive power is proportional to the square of the voltage).

Example memory technologies applicable to 3D heterogeneously interconnected memory as disclosed herein include floating-gate, split-gate, SONOS, floating dot, DRAM, DRAM-like (e.g., 2T0C), 2FeFET, FeFET, 2TR2R, ReRAM, phase change, STT-RAM, NAND-based flash memory technology, NOR-based flash memory technology, and any memory technology compatible with die stacking. Exemplary SO NOS memory technology (sometimes referred to as charge trap memory) uses an insulating layer (e.g., of silicon nitride) with traps to capture and retain charge as injected from a channel. Exemplary floating dot memory technology conceptually replaces a floating gate with a floating silicon nanodot or embeds floating silicon nanodots in a polysilicon gate. Exemplary 2T0C memory technology uses parasitic capacitance of a read transistor to store charge rather than an explicit storage capacitor. Exemplary FeFET memory technology uses permanent electrical field polarization of ferroelectric material embedded between a gate and a source-gate conduction region to store information. Exemplary 2TR2R memory technology uses two transistors and two resistors to collectively store information. Exemplary ReRAM memory technology uses controllable resistance across a dielectric solid-state material (e.g., a memristor) to store information. Exemplary phase change memory technology uses programmable resistance of a phase change material to store information. Exemplary STT-RAM memory technology uses magnetic orientation to store information.

It is understood that the foregoing disclosure presents implementations, variations, embodiments, and examples in an intended illustrative sense rather than in a limiting sense. It is contemplated that modifications and combinations are discernible that will be within the spirit of the disclosure and the scope of the following claims. What is claimed is:

1. A memory component comprising:
an array of memory strings coupled to a Bit Line (BL) and a Common Source Line (CSL), the BL and the CSL enabled to transmit a plurality of signals;
feature logic circuitry;
memory logic circuitry;
a first one or more conductors formed through a corresponding one or more Through-Array Vias (TAVs) enabling communication between the feature logic circuitry and the memory logic circuitry; and
a second one or more conductors formed to contact a corresponding one or more Through-Array Contacts (TACs),
wherein at least one of the plurality of signals is transmitted to at least one of the second one or more conductors.

2. The memory component of claim 1, wherein the BL is coupled to the memory logic circuitry using one of the TACs.

3. The memory component of claim 1, wherein the BL is coupled to the memory logic circuitry using direct bonding.

4. The memory component of claim 1, wherein a feature logic integrated circuit die comprises the feature logic circuitry and a memory logic integrated circuit die comprises the memory logic circuitry.

5. The memory component of claim 4, wherein a memory array die comprises the array of memory strings.

6. The memory component of claim 4, wherein a first operating voltage of the feature logic integrated circuit die is less than a second operating voltage of the memory logic integrated circuit die.

7. The memory component of claim 1, wherein the feature logic circuitry comprises one or more of:
page buffer circuitry,
finite state machine circuitry,
on-demand operation circuitry,
Quality of Service (QOS) boosting circuitry,
read/write performance improving circuitry,
Input/Output (I/O) circuitry,
Field Programmable Gate Array (FPGA) circuitry,
one or more logic circuits enabled to operate at a lower voltage than the memory logic circuitry, and
NAND interface circuitry.

8. The memory component of claim 1, wherein the feature logic circuitry comprises logic circuitry enabled to enhance performance of AI operations, which comprises any one or more of:
an accumulator with shift-and-add and/or inversion operations,
logic circuitry to quickly determine a count and compare the count to another value,
first one or more registers enabled to retain intermediate data, and
second one or more registers enabled to store input patterns.

9. The memory component of claim 1, wherein the feature logic circuitry comprises memory reliability circuitry, which is enabled to perform any one or more of:
Cyclic Redundancy Check (CRC) operations,
checksum operations,
threshold voltage tracking operations, and
error handling flow operations, one or more of the error handling flow operations enabling error correction according to one or more error correcting codes.

10. The memory component of claim 1, wherein the feature logic circuitry comprises asynchronous independent plane operation circuitry, which is enabled control the array of memory strings to perform at least one of (1) asynchronous independent plane program operations and (2) asynchronous independent plane erase operations.

11. The memory component of claim 1, wherein the memory logic circuitry comprises one or more of:
charge pump circuitry,
sense amplifier circuitry,
programming circuitry,
Word Line Driver (WLD) circuitry,
String Select Line (SSL) driver circuitry,
Ground Select Line (GSL) driver circuitry,
one or more transistors coupled to a sense amplifier wherein the one or more transistors optionally comprise one or more BL clamping transistors and/or one or more BL precharge transistors, and
CSL driver circuitry.

12. The memory component of claim 1, wherein the array of memory strings is implemented according to memory technology comprising one or more of:
Resistive Random Access read/write Memory (ReRAM) technology,
phase change memory technology,
Spin-Transfer Torque Resistive Random Access read/write Memory (STT-RAM) technology,
NAND-based flash memory technology, and
NOR-based flash memory technology.

13. A method comprising:
forming first interconnections between a memory logic die and a feature logic die using a first one or more conductors formed through a corresponding one or more Through-Array Vias (TAVs), and
forming second interconnections between an array die and the memory logic die using a second one or more conductors formed to contact a corresponding one or more Through-Array Contacts (TACs);
wherein
the array die comprises an array of memory strings coupled to a Bit Line (BL) and a Common Source Line (CSL), the BL and the CSL transmitting a plurality of signals,
the memory logic die comprises memory logic circuitry,
the feature logic die comprises feature logic circuitry,
the first interconnections enable communication between the feature logic circuitry and the memory logic circuitry using the first one or more conductors, and
the second interconnections enable transmission of at least one of the plurality of signals to at least one of the second one or more conductors.

14. The method of claim 13, wherein
the memory logic die is one of a plurality of memory logic dice of a memory logic wafer,
the feature logic die is one of a plurality of feature logic dice of a feature logic wafer,
the forming of the first interconnections comprises forming interconnections between the memory logic wafer and the feature logic wafer.

15. The method of claim 13, wherein
the array die is one of a plurality of array dice of an array wafer,
the memory logic die is one of a plurality of memory logic dice of a memory logic wafer,
the forming of the second interconnections comprises forming interconnections between the array wafer and the memory logic wafer.

16. A memory component comprising:
an array of memory strings coupled to a Bit Line (BL) and a Common Source Line (CSL), the BL and the CSL transmitting a plurality of signals;
feature logic circuitry;
memory logic circuitry;
a first one or more conductors formed through a corresponding one or more through vias enabling communication between the feature logic circuitry and the memory logic circuitry; and
a second one or more conductors formed to contact a corresponding one or more direct bonds, and
wherein at least one of the plurality of signals is transmitted to at least one of the second one or more conductors.

17. The memory component of claim 16, wherein the through vias comprise Through-Array Vias (TAVs) that extend through the array, and the BL and the CSL are coupled to respective ones of the second one or more conductors.

18. The memory component of claim 16, wherein the through vias comprise Through-Array Vias (TAVs) that extend through the array, and the BL is coupled to the memory logic circuitry by a direct bond.

19. The memory component of claim 16, wherein the through vias comprise Through-Array Vias (TAVs) that extend through the array, and the BL is coupled to the feature logic circuitry by a direct bond.

20. The memory component of claim 16, wherein the through vias comprise through silicon vias, and the BL and the CSL are coupled to respective ones of the second one or more conductors.
